(19) United States
(12) Patent Application Publication
(10) Pub. No.: US 2018/0174832 A1
(43) Pub. Date: Jun. 21, 2018

(54) METHOD AND DEVICE FOR COATING SUBSTRATES

(71) Applicant: EV Group E. Thallner GmbH, St. Florian am Inn (AT)

(72) Inventor: Andreas Fehkuhrer, Senftenbach (AT)

(73) Assignee: EV Group E. Thallner GmbH, St. Florian am Inn (AT)

(21) Appl. No.: 15/542,096

(22) PCT Filed: Oct. 22, 2015
(86) PCT No.: PCT/EP2015/074517

§ 371 Date: Jul. 7, 2017

(30) Foreign Application Priority Data
Jan. 15, 2015 (DE) 10 2015 100 579.4

(51) Int. Cl. H01L 21/02; H01L 21/67

(52) U.S. Cl. CPC H01L 21/02282; H01L 21/02118; H01L 21/67103; H01L 21/6715

(57) ABSTRACT

A method and device for coating a substrate with a film layer. The device comprises application means for applying a thermoplastic film layer material and distribution means for distributing the film layer material on the substrate for the formation of the film layer.

The invention relates to a method according to claim 1 and a device according to claim 10.

In the prior art, the application of a polymer on the surface of a substrate takes place as follows. The substrate, in particular a wafer, is fixed at the underside on a horizontal rotary plate, the sample holder (engl.: chuck) by means of a vacuum suction system. A predefined quantity of a polymer solution, which is mixed with solvent—referred to below solely as a film layer material, is applied with a metering device via the centre of the wafer. The film layer thickness is dependent on the viscosity of the polymer solution, the rotational speed, the rotational acceleration and the process duration of the spin-coating. The final rotational speed and the process duration are controlled on the spin-coater depending on the desired result and the film layer material is distributed from the delivery point, i.e. the approximately concentric centre of the substrate, towards the radially symmetrical edge of the substrate. Any excess film layer material is spun off from the substrate. As a rule, solvent-containing polymer solutions are used for this. The solvent proportion is intended to serve to reduce the viscosity and thus to assist the uniform distribution of the polymer solution on the wafer. The reduced viscosity accelerates the production of the film layer. As a result of the reduction of the viscosity of the polymer solution extending over all areas of the wafer, a particularly large amount of excess material is spun off over the edge of the substrate. To be able to produce a stable film layer, it is necessary in a next step to remove solvent bound in the polymer solution. A part of the solvent volatalises directly during the spinning-off. The remaining solvent concentration is reduced approximately towards zero in a time-intensive manner by subsequent baking-out (engl.: soft bake). This takes place by means of a two-dimensional and one-piece heating zone which extends over the entire area of the sample holder and at least has the size of the substrate to be treated or is slightly larger. The potentially very good homogeneity of the film layer thickness and the short cycle times that are made possible make spin-coating in microelectronics into the method of producing a film layer that is by far the most frequently used.

The substrate is spin-coated with a polymer solution in which a high proportion of solvent has been dissolved. In order to produce a stable film layer, it is first necessary to distribute the film layer material uniformly.

In order to distribute the solvent uniformly, the sample holder on which the substrate to be processed is located is put into a rotational motion. This brings about a distribution of the film layer material over the entire surface of the substrate. The concentric centre of the sample holder forms the radial rotational axis for the substrate.

The distribution of the film layer material is influenced in particular by the viscosity of the polymer solution and the solvent proportion contained therein, the acceleration, the rotational speed and the process duration of the spin-coating. In principle, it can be said that the rotational speed must increase accordingly with increasing viscosity in order to achieve an optimum distribution of the film layer material.

In spin-coating, more film layer material basically has to be used than would actually be required to produce the film layer. The effect of spin-coating, as it is used at the present time, is that there is an increased spin-off of the film layer material present in the radially symmetrical edge region of the substrate. Depending on the solvent proportion and the viscosity resulting therefrom, an additional use of film layer material has to be reckoned with, which in the most favourable case leads to the need for a doubling of the film layer material used. In particular cases, however, a fourfold or higher use of the film layer material may also be necessary, which represents a cost factor that cannot be underestimated.

The spun-off film layer material cannot be reused, since contamination cannot be ruled out. Since the high proportion of solvent in the film layer would disrupt the bonding process, it is necessary to reduce the latter. This can take place by an additional increase in the rotational speed as well as by an increase in the baking temperature or a combination of the two. The increase in the rotational speed, however, leads to a further increase in the part of the film layer material spun off over the substrate edge, as well as a change in the layer thickness.

In principle, it is the case that, during the spin-coating, the remaining solvent concentration at first falls rapidly and then saturates at a value which depends in particular on the film layer thickness and which can only be removed further at higher temperatures. To achieve this, baking-out takes place during which the solvent can be further reduced. The baking-out as such is likewise not trivial, since this process has to be carried out in different temperature steps. The different temperature steps are necessary in order to prevent bubble formation—which would arise in the case of excessively rapid heating. Since the quantity of solvent to be baked out is determined primarily by the film layer thickness, it remains the case that, with an increasing film layer thickness, the amount of time spent on baking out the solvent present in the individual film layers increases proportionally.

Conversely, it is of course the case that the thinner the film layer is formed, the baking-out time is reduced accordingly. The thickness of the film layer cannot however be freely selected, but rather is determined by the given demands on such a film layer. Notwithstanding this, it is the case that the process step of baking-out when using solvent-containing polymer solutions is absolutely essential and at all events has the effect of impeding the process flow.

The problem of the present invention, therefore, is to develop the generic devices and methods for coating substrate in such a way that efficient coating is enabled, in particular when used in bonding.

This problem is solved with the features of claims 1 and 10. Advantageous developments of the invention are given in the sub-claims. All combinations of at least two features given in the description, in the claims and/or the drawings also fall within the scope of the invention. In the case of value ranges, values lying inside the stated limits are also deemed to be disclosed as limiting values and can be claimed in any combination.

The basic idea of the present invention is to use an in particular solvent-free thermoplastic for the coating of a substrate with a film layer, said thermoplastic being applied by means of a device (application means) suitable for applying the thermoplastic.

The invention relates in particular to a method and a device, with which coating, preferably spin-coating, of a substrate, in particular a wafer, takes place with an in particular solvent-free thermoplastic.

The invention describes in particular a method and a device, which provides for the use of an in particular solvent-free thermoplastic for the production of film layers on substrates. The addition of solvents to reduce the viscosity is preferably thereby completely dispensed with. Moreover, the invention relates in particular to a device with which it is possible to distribute the thermoplastic serving to produce a film layer uniformly on a substrate surface, in particular irrespective of the form in which it is present. Uniform distribution is understood here to mean both the homogeneity of the applied material and also the film layer thickness.

In principle, the use of all known types of thermoplastics is conceivable. According to the invention, the following are preferred, individually or in combination:
bonding adhesives, in particular cycloolefin copolymers
polyethylene (PE),
polypropylene (PP),
polystyrene (PS),
polyvinyl chloride (PVC),
polyamide (PA),
polyimide (PI),
polymethyl methacrylate
acrylonitrile butadiene styrene (ABS) with a melting temperature of 220-250° C.,
polyamides (PA) with a melting temperature of 178-260° C.,
polyactides (PLA) with a melting temperature of 150-160° C.,
polymethyl methacrylate (PMMA) with a melting temperature of 105° C.,
polycarbonate (PC) with a melting temperature of 280-320° C.,
polyethylene terephthalate (PET) with a melting temperature of 250-260° C.,
polyethylene (PE) with a melting temperature of 80-100° C., (PE-LD, 80° C.), (PE-HD, 100° C.), (PE-LLD, 30-90° C.),
polypropylene (PP) with a melting temperature of 160-165° C., in particular with the addition of small amounts of solvents,
polystyrene (PS) with a melting point of 240° C. in the case of isotactic PS and 270° C. in the case of syndiotactic PS,
polyether ether ketone (PEEK) with a melting point of 280° C.,
and/or
polyvinyl chloride (PVC) with a melting point of 79° C., in particular with the addition of solvent.

In addition, thermoplastics not yet known today are also intended which in characteristics, i.e. material behaviour etc., have similar properties to the aforementioned film layer materials. These include in particular mechanical properties, especially the melting temperature.

The invention in particular makes provision for the use of a solvent-free thermoplastic for producing a film layer on a substrate, in particular a wafer.

Thermoplastic is a plastic which, depending on the ambient parameters such as pressure, temperature, can basically have four different aggregate states, namely solid, thermoelastic, thermoplastic and liquid. According to the invention, thermoplastics are preferably used that do not cross-link and can be liquefied and hardened repeatedly, in particular with arbitrary frequency, in a reversible manner.

The thermoplastic is applied on the surface of a substrate by an application means. The application means is in particular an extruder. In order to bring about, via an extruder device, an application of a thermoplastic (generally: film layer material) that is present in particular in solid form in the extruder device, the aggregate state of the film layer material is changed from solid to liquid by the supply of heat, in particular in the extruder device. This preferably takes place by means of a heat source present in the extruder. As a result of the change in the aggregate state, it is possible to deliver the film layer material via the extruder onto the substrate surface. The quantity of the film layer material to be applied on the substrate surface is dependent on the desired film layer thickness.

The application means comprise in particular an opening via which the thermoplastic exits. The opening can in particular be swept with gases and/or gas mixtures in order to prevent premature oxidation of the thermoplastic. The gases used are preferably
Noble gases, in particular
   Ar, He, Kr, Xe,
Inert gases
   N2, CO2

The extruder operates in particular at a processing temperature between 25° C. and 500° C., preferably between 50° C. and 500° C., still more preferably between 100° C. and 500° C., most preferably between 250° C. and 500° C., with utmost preference between 300° C. and 500° C.

The extruder operates in particular at a processing pressure between 1 bar and 1000 bar, more preferably between 10 bar and 1000 bar, most preferably between 100 bar and 1000 bar, with utmost preference between 500 bar and 1,000 bar.

In order to be able to maintain the aggregate state and in particular the viscosity also during the delivery of the film layer material onto the substrate, provision is made according to an embodiment of the invention to supply heat in particular in a narrow temperature range. This temperature range is material-dependent and is derived from the viscosity curve.

Some viscosity curves have a viscosity minimum of the viscosity as a function of the temperature. The limits of the preferred temperature range according to the invention are indicated as plus/minus values in relation to this viscosity minimum. The temperature range lies in particular between −50° C. and +50° C., preferably between −30° C. and +30° C., still more preferably between −10° C. and +10° C., still more preferably between −5° C. and +5° C., most preferably between −1° C. and +1° C. around the temperature value at which the viscosity minimum of the viscosity curve is located. The viscosity minimum of the viscosity curve is preferably a global minimum. If the viscosity curve has a number of minima and if it proves to be expedient, it may be advisable according to the invention to select a non-global minimum.

If the viscosity curve does not have a minimum, but rather exhibits a continuous decline of the viscosity with increasing temperature, a temperature is preferably selected at which the viscosity of the thermoplastic is correspondingly low. This temperature preferably lies above 25° C., preferably above 50° C., still more preferably above 100° C., most preferably above 150° C., with utmost preference above 250° C.

By means of a temperature range selected as narrow as possible, the low viscosity of the film layer material present during the application onto the substrate is kept as constant as possible at least at the start of the distribution and the film layer material is distributed homogeneously on the substrate. The addition of solvent for the purpose of reducing the viscosity is for this reason unnecessary throughout the entire process of distributing the film layer material.

The application of the film layer material preferably takes place at a central point, in particular approximately in the concentric centre of the substrate. Following the delivery of the film layer material from the extruder device onto the substrate surface, the film layer material is distributed over the entire area of the substrate (distribution means), especially by rotation means.

Since cooling that starts after the delivery of the thermoplastic onto the substrate could impede the uniform distribution, the sample holder receiving the substrate can be heated according to an embodiment of the invention with a heating device, in particular integrated into the sample holder. In a particular embodiment according to the invention, the sample holder is heated to the same temperature as the application means, in particular the extruder, in order for the most part to prevent cooling of the polymer to be applied.

In a development of the heating device, the latter comprises separately controllable heating zones, which in a particularly advantageous embodiment are arranged in an annular manner, in particular concentrically, on the sample holder or are integrated therein. In particular, partial annular heating of the substrate can thus take place depending on a temperature profile previously prepared for the given case of application. As a result of the separately controllable heating zones, the adjustment of a heating profile, and therefore of a temperature distribution with which the temperature is given as a function of the radial position, is possible.

On the basis of the fact that the flow rate of the solvent towards the radially symmetrical edge increases with widening with a constant rotational speed, the viscosity of the film layer material can be influenced by a differing exposure to heat along concentric sections. The viscosity is preferably kept lower in the centre then towards the edge, in order to promote a more rapid distribution into the radial edge region. The viscosity is preferably reduced towards the edge region, in order to reduce to a minimum excessive spinning-off of film layer material over the lateral edge of the substrate or even to prevent it completely.

According to a further advantageous embodiment, provision is made such that the first substrate and/or the second substrate is rotated during the application of the film layer. The rotational speed of the substrate fixed on the sample holder that is to be applied at the minimum to produce the desired film layer is not solely dependent on the in particular locally controlled heat input and the possibility thus arising of changing the viscosity. On the contrary, an optimum distribution can be brought about by a combination with a rotation speed, without excessive film layer being wasted.

In a development of the invention, the melt flow index (engl.: mass flow rate, MFR) of the film layer material is particularly decisive for the adjustment of the rotation and/or the temperature, since said melt flow index characterises the flow behaviour and the time when the flowability of the thermoplastic used is reached. The melt flow index is determined for a defined temperature and a defined pressure. The measurement preferably takes place in a capillary rheometer. The sample to be investigated is heated to a defined temperature and pressed by an application of pressure, in particular by a calibration weight, through a capillary. The measured mass per time unit, in particular per 10 minutes, is then a measure for the melt flow index. The unit of the melt flow index is given in g/(10*min). The greater the value, the less viscous the thermoplastic. Since the melt flow index applies to a specific temperature and a specific pressure, guidance values are stated here for wide temperature and/or pressure ranges. The melt flow index of the film layer material is in particular greater than 10E-3 g/(10*min), preferably greater than 10E-1 g/(10*min), still more preferably greater than 10 g/(10*min), most preferably greater than 100 g/(10*min), with utmost preference greater than 1000 g/(10*min).

By means of annular heating elements which can be heated separately and in a differentiated manner and which extend around the concentric centre of the sample holder, it is possible to heat the radial edge region of the substrate less intensively, which has a direct influence on the viscosity in these regions. For this purpose, the heating elements are heated in such a way that the heat input becomes less from the concentric centre of the sample holder towards the radially symmetrical edge region, wherein the flow rate is in particular kept constant.

According to the invention, an increase in the viscosity in the radially symmetrical edge region of the substrate is preferred, and resulting therefrom a reduction in the film layer material being spun out over the edge of the substrate.

The creation of associated sets of parameters (formulations) for controlling the rotation, in particular the rotational speed and therefore the centrifugal forces, and the heat input, in particular in preferably separately controlled heating elements of the sample holder, represents an, in particular independent, aspect of the present invention. The thermoplastic properties of the given film layer material are preferably taken into account, in particular by the creation of specific sets of parameters for each film layer material or for each combination of a film layer material and a substrate. The following, in particular typical, sets of parameters and formulations are stated by way of example, but are not limiting.

| Rotational speed | Acceleration | Temperature |
|---|---|---|
| (rpm) | (rpm/s) | (° C.) |
| 100-10000 | 100-5000 | 25-500 |
| 100-10000 | 100-5000 | 100-500 |
| 100-5000 | 100-5000 | 100-500 |
| 100-2500 | 100-5000 | 100-500 |

In particular, in addition to the centrifugal forces, acting Coriolis forces are taken into account in the creation of the formulations. The Coriolis force is directly proportional to the angular speed of the rotating substrate, and directly proportional to the speed of the propagating thermoplastic. It can thus be reduced by a reduction in the angular speed and/or the speed of the propagating thermoplastic. If, for example, the speed of the propagating thermoplastic is increased due to a higher temperature and an associated lower viscosity, the angular speed can be reduced correspondingly, in order to reduce or to prevent the Coriolis force. In particular, the desired layer thickness is also taken into account, so that the parameters are in particular set in such a way that the requirements for the distribution of the thermoplastic on the substrate are complied with. The parameters can in particular be determined empirically.

A process according to the invention for coating substrates with thermoplastic in the semiconductor industry can be improved in particular by the fact that the film layer material is applied, in particular deposited, continuously in a rod-like form, continuously as roll material or as ready-made pads, by means of at least one application means onto the substrate, in particular a wafer. The film layer material is preferably applied in combination with a sample holder forming a plurality of heating zones. The application means then acts as a kind of glue gun. The supply of rods or pads by means of an extruder is also conceivable, as long as the latter can be processed with the extruder.

In a development of the invention, the thermoplastic is fed as a granulate to the application means, in particular to the extruder.

By the use of a thermoplastic comprising in particular a solvent proportion less than 80%, preferably less than 60%, still more preferably less than 40%, much more preferably less than 20%, most preferably less than 1%, with utmost preference a solvent-free thermoplastic, the time-intensive baking-out of a solvent at different temperatures is completely eliminated or is at least markedly reduced. Moreover, an increased rotational speed, which serves to reduce the solvent, can be dispensed with. A higher throughput is thus achieved, to which particular importance is attached especially in the high-volume manufacturing sector.

By using an application means, in particular an extruder device, which is in particular independent according to the invention, the thermoplastic can be delivered in a metered manner onto the substrate surface as required, in particular in a previously defined quantity required for the production of the given film layer. By means of annular and/or mutually independently heatable heating elements or heating zones, it is possible to heat the radial edge region of the substrate less intensively, which has a direct influence on the viscosity of the film layer material during application. Accordingly, an increase in the viscosity in the in particular radially symmetrical edge region of the substrate arises and, as a result of this, a reduction in the film layer material spun out over the edge of the substrate.

In a development of the heating means for heating the substrate, in particular integrated into the sample holder, and of the application means, in particular the extruder device, the heating means and the application means, in particular the extruder device, are operated/controlled independently of one another. In this way, thermal inputs of the application means, in particular of the extruder, and of the heatable sample holder can diverge from one another. In particular, the temperature of the thermoplastic to be deposited via the application means, in particular the extruder, can be markedly above the temperature of the substrate holder in order to achieve a low viscosity. In particular, the temperature also lies above the temperature required for a bonding process.

Moreover, the invention is based on the idea of developing a method and a device with which it is possible, by means of an application means, in particular an extruder, to implement the application of an in particular solvent-free thermoplastic in a controlled manner for the production of a predefined film layer onto substrates used in the semiconductor industry.

An alternative device according to the invention comprises:
an application means, in particular an extruder device, for the controlled heating and delivery of an in particular solvent-free thermoplastic onto a substrate to be processed,
a sample holder comprising a multiplicity of heating elements, in particular constituted in an annular form, which can be completely integrated into the sample holder, and
a heating device with an associated control, which in particular is set up in such a way that the temperature on the application means, in particular on the extruder device, and the heating of the sample holder can be regulated independently of one another.

In particular, a multiplicity of heating elements is disclosed, which can be heated independently of one another, preferably steplessly, and which can also be part of the sample holder. The heating elements can preferably be actively cooled in order that cooling to a desired temperature can take place more quickly. The number of heating elements therefore amounts to at least two heating elements, preferably more than two heating elements, most preferably more than ten heating elements, with utmost preference more than 20 heating elements. In cross-section, the heating elements are in particular constituted rectangular, in order to enable a plane-parallel contact directly or indirectly with the substrate. In principle, however, any other cross-sectional geometry is also conceivable that enables a claimed contact heat transfer. The heating elements can moreover be spaced apart from one another and/or be isolated, in order to prevent an uncontrolled and undesired release of heat to adjacent heating elements and therefore heating zones.

An individual heating element can also take effect as an independently operating heating zone. Similarly, it is advantageously possible to combine a plurality of heating elements to form a heating zone, i.e. to form groups and to control the latter by means of the control unit.

The heating elements extend in particular over the entire sample holder and are preferably arranged in an annular manner around the concentric centre of the sample holder. The heating elements can be both an integral component of the sample holder and can also comprise individual segments, which are in contact with the underside of the sample holder in a plane-parallel manner and thus enable an indirect heat transfer. The side of the sample holder facing the substrate, which is provided as a contact face with the substrate, is preferably constituted plane-flat.

The method and the device are operated, in particular in an automated manner, with tried and tested formulations, in particular empirically optimised value-collections of parameters (sets of parameters), which are connected functionally and in terms of the process. The use of formulations is therefore particularly important for the device and the method according to the invention, because a reproducibility of process sequences can thus be guaranteed, which in turn directly influences the quality of the result to be expected. Moreover, a greater ease of operation of the device according to the invention thus arises.

Notwithstanding this, a manual control by a machine operator is also conceivable.

The substrates (first and/or second substrate) are preferably wafers. The wafers are standardised substrates with defined, in particular standardised, diameters. Standardised diameters of 1, 2, 3, 4 inches or 125 mm, 150 mm, 200 mm, 300 mm or 450 mm are preferably selected as diameters of the substrates. The coating of rectangular substrates is however also conceivable.

According to an advantageous embodiment, the aforementioned devices are located at least partially, preferably completely in an evacuatable and/or heatable environment, preferably in a process chamber, which in particular can be swept with gas, in order to create ideal conditions for a subsequent bonding process. The method according to the invention takes place in this embodiment at least partially, preferably completely, in the bonding chamber, wherein in particular the first substrate is bonded with the second substrate as an additional step at the end. The process chamber can in particular be evacuated to a pressure of less than 1 bar, preferably less than 10⁻³ mbar, still more preferably less than 10⁻⁴ mbar, most preferably less than 10⁻⁵ mbar, with utmost preference less than 10⁻⁶ mbar.

The method according to the invention in particular makes provision to place an in particular preheated carrier substrate, preferably a polymer substrate, onto a heatable sample holder and then to adjust it to the temperature of the sample holder. After the adjustment of the temperature has taken place, the application of the thermoplastic (generally: film layer material), in particular a plastomer, takes place by means of the application means, in particular the extruder device, onto the surface of the substrate. The application can in particular take place at the moment when the thermoplastic, as a result of reaching a specific temperature range, can be deformed thermoplastically. The flowability is in particular not achieved by the addition of a solvent, but preferably exclusively by the heating of the thermoplastic. The aim, therefore, is that the thermoplastic is brought into a molten state and kept in this molten state until the completed application on the substrate. A temperature range is preferably selected, wherein the phase change is reversible. Overheating of the thermoplastic is accordingly preferably avoided. In the event of overheating, a disadvantageous thermal decomposition of the thermoplastic would result.

This application of the film layer material takes place in particular by means of an extruder (extruder device), wherein an extrusion opening of the extruder is preferably located in the X-plane (substrate surface or parallel thereto) approximately in the concentric centre of the sample holder and in the Z-direction close to the substrate surface. The application point is located in the X-plane also directly in the region of the concentric centre of the sample holder and in the Z-direction on the substrate surface. Similarly, this also applies to a rod-like application of the film layer material.

In order that the thermoplastic cools down as little as possible during the transfer from the extruder onto the surface of the sample holder, the extrusion opening is arranged in particular as close as possible to the surface of the substrate. The distance between the extrusion opening and the surface of the substrate is in particular less than 100 mm, more preferably less than 50 mm, most preferably less than 25 mm, most preferably less than 10 mm, with utmost preference less than 1 mm. The same also applies to a rod-like application of the film layer material.

The sample holder can already be in a rotational motion (rotation) when the application of the film layer material takes place on the substrate surface, in order to achieve a planar distribution of the film layer material over the entire substrate. A rotational motion that only starts when the application of the film layer material on the substrate has taken place is however also conceivable. In this regard, it is advantageous to control the deposition process in such a way that the quantity of the film layer material delivered to the surface of the substrate is related to the rotational speed of the centre point rotating around the radially symmetrical centre of the substrate and that a distribution towards the radially symmetrical edge of the substrate can take place. The rotational speed is given in revolutions per minute (engl.: rounds per minute, rpm). The rotational speed is in particularly greater than 1 rpm, preferably greater than 10 rpm, still more preferably greater than 100 rpm, most preferably greater than 1000 rpm, with utmost preference greater than 10000 rpm. The rotational acceleration is given in revolutions per minute per second (engl.: rounds per minute per second, rpm/s). The rotational acceleration is in particularly greater than 1 rpm/s, preferably greater than 10 rpm/s, still more preferably greater than 100 rpm/s, most preferably greater than 1000 rpm/s, with the utmost preference greater than 5000 rpm/s.

The viscosity is a physical property which is temperature-dependent. The viscosity of the film layer material preferably diminishes with increasing temperature. The viscosity of the film layer material lies particularly at room temperature between 10e⁶ Pa*s and 1 Pa*s, preferably between 10e⁵ Pa*s and 1 Pa*s, still more preferably between 10e⁴ Pa*s and 1 Pa*s, most preferably between 10e³ Pa*s and 1 Pa*s.

The thermal input at the sample holder is in particular controlled in such a way that the latter diminishes from the concentric centre of the sample holder towards the radially symmetrical edge region of the sample holder. The viscosity (physical magnitude dependent on the temperature) of the film layer material, therefore, is lower close to the concentric centre of the substrate/sample holder than in the radially symmetrical edge region of the substrate/sample holder.

The thermal input with which the heating elements are heated lies in particular in a range from 25° C. to max. 500° C., preferably between 100° C. and 500° C., still more preferably between 250° C. and 500° C., with utmost preference between 300° C. and 500° C. Each heating element is preferably individually controllable, i.e. heatable and/or individually regulatable and/or actively coolable. The heat input is advantageously guided in particular by the known/specified material properties of the employed film layer material and/or of the already known temperature range of the film layer material (difference between an upper and lower limiting temperature of the respectively used film layer material, in particular a thermoplastic). The temperature difference from one heating element, in particular heating ring, to an adjacent heating element preferably amounts to less than 10° C., still more preferably less than 5° C. Furthermore, there is the possibility of linking together a plurality of heating elements, in particular heating rings, and thus of forming heating zones comprising a plurality of heating rings. The temperature of the heating element or at least of the substrate remains at all times below the critical temperature value for the film layer material, in particular below 300° C., because otherwise thermal decomposition of the film layer material could occur.

The melt flow index of the film layer material, in particular a thermoplastic, is specific to the film layer material used. Some thermoplastics, also able to be used according to the invention, can achieve a flowable state only with the addition of solvent such as for example acetone. These kinds of thermoplastics are also claimed according to the invention, since only very small quantities of solvent need to be added (compared to the methods known in the prior art), in order to achieve the flowability/flow rate aimed at according to the invention. The thermal input to achieve a flowable state of the film layer material, in particular a thermoplastic, lies in particular in a range from 80-280° C.

The thermal input preferably takes place in such a way that, in the region of the concentric centre on the substrate surface, a temperature is reached at which an optimum melt flow index is present for the film layer material used, which enables the thermoplastic to exit from the extrusion opening in a suitable quantity per unit of time. The heating means are moreover suitable for holding this temperature, in particular in a controlled manner, permanently or constantly between −20° C. and +20° C., preferably between −10° C. and +10° C., still more preferably between −5° C. and +5° C., most preferably between −2° C. and +2° C., with utmost preference between −1° C. and +1° C., of the specified or adjusted temperature.

In particular, the heat input in the vicinity of the concentric centre of the substrate is higher than in the radially symmetrical edge region of the substrate, where spinning-off of excess film layer material is prevented as far as possible or at least markedly reduced by a higher viscosity.

The heat input to be adjusted is thus primarily determined by the melt flow index and/or the critical temperature applicable to the film layer material used, at which critical temperature a thermal decomposition occurs. The range of the heat input can be such that the film layer material used passes through all the aggregate states from the application means, in particular the extruder device, up to the distribution in the radially symmetrical edge region of the substrate.

In a particular development of the invention, a substrate coated, in particular lacquered, by means of the inventive process or the inventive embodiment, is bonded after the coating, in particular immediately. According to the invention, evaporation of a solvent in particular is no longer necessary, which markedly improves the process time between the lacquering and the bonding. The time between the end of the coating and the start of the bonding process is in particular less than 10 minutes, preferably less than 5 minutes, still more preferably less than 3 minutes, most preferably less than 1 minute, with utmost preference less than 30 seconds. Such short time intervals cannot be achieved with evaporation steps and therefore represent a decisive improvement of the invention.

In a first embodiment of a process according to the invention, the following steps take place, in particular in this sequence.

In the first process step, a substrate, in particular a carrier substrate, is loaded onto an in particular temperature-regulated sample holder.

In a second process step, the substrate is brought to the temperature of the sample holder.

In a third process step, the substrate is accelerated to a preset rotational speed.

In a fourth process step, the in particular solvent-free thermoplastic is deposited by the application means on the surface of the substrate facing away from the sample holder.

The sample holder is held still in a fourth step.

In a fifth process step, the thermoplastic applied on the substrate is cured, in particular by cooling of the coated substrate. The cooling takes place in particular either by a gas introduced into the chamber and/or by active cooling of the sample holder.

Further advantages, features and details of the invention emerge from the description of preferred examples of the embodiment and on the basis of the drawings. In the figures:

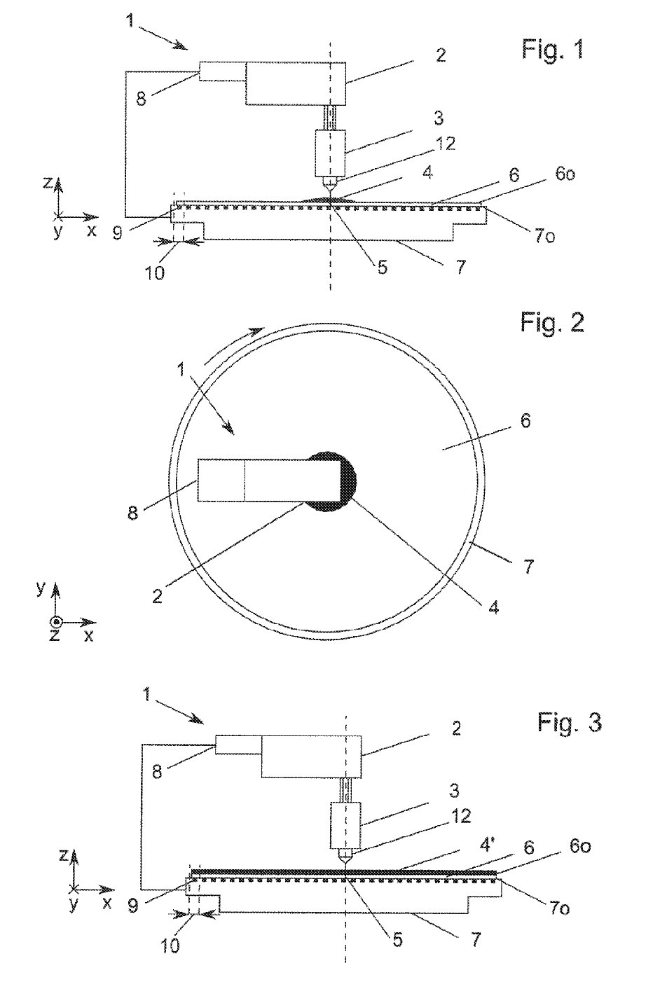

FIG. 1 shows a diagrammatic cross-sectional view of an embodiment of a device according to the invention,

FIG. 2 shows a plan view of the embodiment according to FIG. 1,

FIG. 3 shows a diagrammatic cross-sectional view of an embodiment of a device according to the invention after the distribution of the thermoplastic,

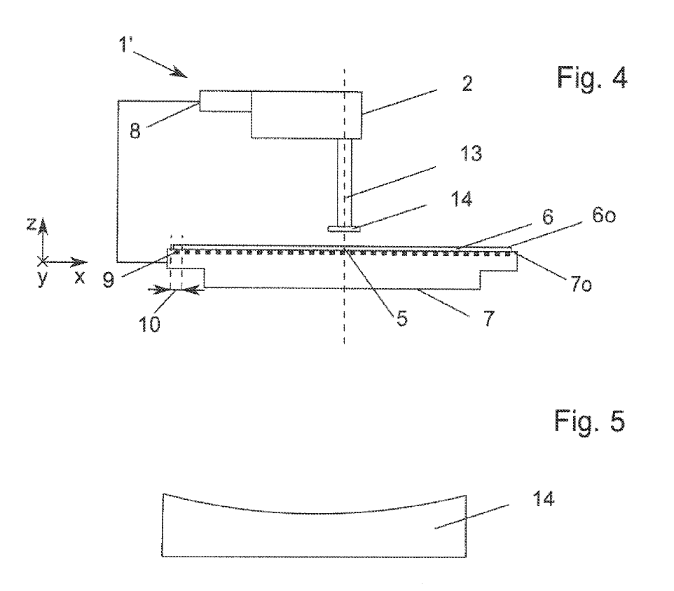

FIG. 4 shows a diagrammatic cross-sectional representation of a further embodiment of a device according to the invention and

FIG. 5 shows a diagrammatic cross-sectional representation (not true to scale) of a preferred pad geometry.

FIG. 1 shows an application means 1 with a heating 2 and an associated delivery region 3 for delivering a film layer material 4 through an opening 12, in particular a nozzle. Application means 1 is preferably constituted as an extruder and then has corresponding extruder-typical components such as screws, which liquefy the thermoplastic, which is present in particular as a granulate, by means of temperature and or pressure. In a further embodiment according to the invention, application means 1, in particular constituted as a glue gun, can be constituted in such a way that the thermoplastic, in particular in rod form, is moved through heating means 2 and/or the delivery region. In a further embodiment according to the invention, a plurality of materials, in particular different thermoplastics or thermoplastics with additives, can be mixed in particular in delivery region 3.

Furthermore, a sample holder 7 for receiving and temporarily fixing a substrate 6 on a receiving surface 7o of sample holder 7 is shown, said sample holder being rotatable by rotation means. Substrate 6 is preferably aligned concentrically on sample holder 7. Sample holder 7 comprises, on its receiving surface 7o, in particular concentrically running and/or spaced-apart and/or mutually isolated heating elements 9 for heating substrate 6.

Opening 12 is or can be arranged above a substrate surface 6o of substrate 6 with as small a distance as possible from substrate surface 6o. With reference to an X-plane (parallel to substrate surface 60), opening 12 is arranged approximately over concentric centre 5 of substrate 6 and likewise the concentric centre of sample holder 7.

A combined control unit 8 controls application means 1 and annular heating elements 9 and/or the alignment and temporary fixing of substrate 6 on sample holder 7.

Substrate 6 is first aligned, applied and temporarily fixed, with its side facing away from substrate surface 6o, on receiving surface 70. Concentric centre 5 both of substrate 6 and also sample holder 7 thus coincide in the X-plane.

Film layer material 4, here a thermoplastic, is applied through opening 12 of application means 1 onto concentric centre 5 of substrate 6.

Film layer material 4 on substrate surface 6o is then accelerated by the rotation means of sample holder 7 from concentric centre 5 towards an edge region 11, wherein heating elements 9 are controlled in such a way that the viscosity of the film layer material continuously diminishes from concentric centre 5 up to edge region 11. The rotational speed remains constant, in particular before the application of film layer material 4 until edge region 11 is reached. The viscosity is controlled by the temperature of heating elements 9 in heating zones 10 in such a way that film layer material 4′ is distributed on substrate 6 for the formation of a film layer with a constant thickness (see FIG. 3).

FIG. 4 shows an alternative application means 1′ according to the invention, wherein ready-made pads 14 formed from the film layer material are centred by means of a holding device 14 over substrate 6 and then placed on substrate surface 6o of substrate 6. Heating of ready-made pads 14 by heating means 2 via holding device 13 is also conceivable, so that the thermoplastic of pad 14 flows to the centre of the substrate, in particular continuously and without droplet formation.

According to an, in particular independent, embodiment, pads 14 are constituted with a plane seating surface and a concave upper side lying opposite the seating surface (see FIG. 5). As a result, peaks, in particular in the centre of substrate surface 6o, are avoided during the formation, in particular distribution, of the coating.

### REFERENCE LIST

1, 1′ application means
2 heating means
3 delivery region
4, 4′ film layer material
5 concentric centre
6 substrate
6o substrate surface
7o receiving surface
7 sample holder
8 control unit
9 heating elements
10 heating zones
11 edge region
12 opening
13 holding device
14 pad

1-10. (canceled)

11. A device for coating a substrate with a film layer, the device comprising:
application means for applying a thermoplastic film layer material onto the substrate, wherein the application means includes at least one extruder device, and
distribution means for distributing the film layer material on the substrate to form the film layer.

12. The device according to claim 11, wherein the distribution means includes rotation means for rotating the substrate during application of the thermoplastic film layer material onto the substrate.

13. The device according to claim 11, wherein the distribution means includes heating means for heating the substrate during application of the film layer material onto the substrate.

14. The device according to claim 13, wherein the heating means subjects the substrate to different heating temperatures.

15. The device according to claim 14, wherein the heating temperatures diminish from a concentric centre of the substrate towards an edge region of the substrate.
